(19) United States
(12) Patent Application Publication
(10) Pub. No.: US 2023/0354685 A1
(43) Pub. Date: Nov. 2, 2023

(54) METHOD FOR MANUFACTURING DEVICE COMPRISING CHARGE TRANSPORT LAYER

(71) Applicants: GLOBAL FRONTIER CENTER FOR MULTISCALE ENERGY SYSTEMS, Seoul (KR); RESEARCH & BUSINESS FOUNDATION SUNGKYUNKWAN UNIVERSITY, Gyeonggi-do (KR)

(72) Inventors: Hyun Suk JUNG, Seoul (KR); Gill Sang HAN, Gyeonggi-do (KR); Min Hee KIM, Gyeonggi-do (KR)

(21) Appl. No.: 17/311,238

(22) PCT Filed: Dec. 17, 2019
(86) PCT No.: PCT/KR2019/017860

§ 371 Date: Jun. 4, 2021

(30) Foreign Application Priority Data
Dec. 19, 2018 (KR) 10-2018-0164711

(51) Int. Cl. H10K 71/15; H10K 71/30

(52) U.S. Cl. CPC H10K 71/15; H10K 71/30; H10K 30/86

(57) ABSTRACT

The present invention relates to a method for forming a charge transport layer on a substrate. Specifically, the present invention provides a method for manufacturing a device comprising a charge transport layer, which enables a uniform charge transport layer to be formed by a solution process even on a large area substrate. The method for manufacturing a device comprising a charge transport layer, of the present invention, may comprise: a charge forming step of forming first polarity charges on a transparent conductive substrate; a polymer electrolyte coating forming step of forming, on the transparent conductive substrate on which the first polarity charges are formed, a polymer electrolyte coating layer of second polarity charges which have the opposite polarity to that of the first polarity charges; and a first charge transport layer forming step of coating the polymer electrolyte coating layer with nanoparticles having the first polarity charges so as to form a first charge transport layer.

### TECHNICAL FIELD

This application claims the benefit of priority to Korean Patent Application No. 10-2018-0164711, filed on Dec. 19, 2018, the entire disclosure of which is incorporated herein by reference.

The present invention relates to a method for forming a charge transport layer on a substrate, and more particularly, to a method for manufacturing a device comprising a charge transport layer, which enables a uniform charge transport layer to be formed by a solution process even on a large-area substrate.

### BACKGROUND ART

An organic-inorganic composite perovskite solar cell which includes a perovskite-structured light absorber has currently been in the spotlight as a next-generation solar cell with achieving renewal of an energy conversion efficiency of 25.2%. Along with such efficiency renewal, interest in modularization and commercialization of perovskite solar cells is increasing, but perovskite solar cells manufactured by a method in which the entire process is constituted by a solution process, has a limitation in large area.

The perovskite solar cell may be formed in a structure in which a transparent conductive substrate, an electron transport layer, a light absorption layer, a hole transport layer, and a rear electrode are stacked. The solution process has been concentrating only on studies on the large area of perovskite light absorption layer, whereas studies on the large area of the electron transport material or hole transport material, which are constituent materials of perovskite solar cells, are insignificant.

In particular, such charge transfer materials are formed on an electrode substrate. As the charge transfer material, an oxide semiconductor having a large band gap is used, and TiO₂ is mainly used. The charge transport layer in which the charge transfer materials are stacked is mainly formed by a solution process. However, due to the characteristics of the solution process, the charge transport layer is formed into a non-uniform thin film on a large-area substrate and defects in the characteristics of perovskite solar cells such as pin holes may occur. Due to pin holes, the shunt resistance and fill factor decrease and thus there is a problem of lowering efficiency in a large-area substrate.

Korean Patent Publication No. 10-2018-0121087 discloses a technique for “Fabrication method of a large area perovskite solar cell”.

### DETAILED DESCRIPTION OF THE INVENTION

### Technical Problem

The present invention relates to a method of forming a charge transport layer on a substrate, and more particularly, to a method for manufacturing a device comprising a charge transport layer, which enables a uniform charge transport layer to be formed by a solution process even on a large-area substrate.

The technical problems to be achieved by the present invention are not limited to the technical problems mentioned above, and still other technical problems that are not mentioned will be clearly understood by those of ordinary skill in the art to which the present invention pertains from the following description.

### Solution to Problem

The method for manufacturing a device comprising a charge transport layer of the present invention may comprise:
a charge forming step of forming first polarity charges on a transparent conductive substrate,
a polymer electrolyte coating forming step of forming a polymer electrolyte coating layer of second polarity charges which have the opposite polarity to that of the first polarity charges on the transparent conductive substrate on which the first polarity charges are formed, and
a first charge transport layer forming step of coating the polymer electrolyte coating layer with nanoparticles having the first polarity charges so as to form a first charge transport layer.

The method for manufacturing a device comprising a charge transport layer of the present invention may comprise:
after the first charge transport layer forming step,
a light absorption layer forming step of forming a light absorption layer on the first charge transport layer,
a second charge transport layer forming step of forming a second charge transport layer on the light absorption layer, and
an electrode forming step of forming an electrode on the second charge transport layer.

In the method for manufacturing a device comprising a charge transport layer of the present invention, one of electrons and holes may be selected as majority carries of the first charge transport layer, and the other may be selected as majority carriers of the second charge transport layer.

In the method for manufacturing a device comprising a charge transport layer of the present invention, in the charge forming step, first polarity charges may be formed on the transparent conductive substrate by treatment with at least one of UVO (ultraviolet-ozone), plasma, and RCA.

In the method for manufacturing a device comprising a charge transport layer of the present invention, the polymer electrolyte coating forming step may comprise preparing a polymer electrolyte solution by dissolving a conductive polymer in a basic solution, and applying the polymer electrolyte solution to the transparent conductive substrate.

In the method for manufacturing a device comprising a charge transport layer of the present invention, the conductive polymer may comprise one or more selected from PAH (polyallylamine hydrochloride), PDADMAC (poly (diallyldimethylammonium chloride)), PEI (poly(ethyleneimine)), PVBT (poly(vinylbenzyltriamethylamine)), PAN (polyaniline), PPY (polypyrrole) and poly(pyridium acetylene).

In the method for manufacturing a device comprising a charge transport layer of the present invention, the first charge transport layer forming step may comprise dispersing the nanoparticles having the first polarity charges in a polar solution and applying the solution in which the nanoparticles are dispersed on the polymer electrolyte coating layer.

In the method for manufacturing a device comprising a charge transport layer of the present invention, when first polarity charges are negative charges, a pH value of the polar solution may be greater than or equal to the isoelectric point of the nanoparticles and when first polarity charges are positive charges, a pH value of the polar solution may be equal to or less than the isoelectric point of the nanoparticles.

In the method for manufacturing a device comprising a charge transport layer of the present invention, the first polarity charges may be negative charges, and the polar solution may be a basic solution which is an aqueous solution having a pH of 8 to 15.

In the method for manufacturing a device comprising a charge transport layer of the present invention, the first charge transport layer forming step may be performed one time.

In the method for manufacturing a device comprising a charge transport layer of the present invention, an average size of the nanoparticles may be 5 to 10 nm.

In the method for manufacturing a device comprising a charge transport layer of the present invention, the nanoparticles may be n-type semiconductor nanoparticles or p-type semiconductor nanoparticles.

In the method for manufacturing a device comprising a charge transport layer of the present invention, the n-type semiconductor nanoparticles may comprise oxides of one or more metals selected from aluminum, titanium, tin, zinc, tungsten, zirconium, gallium, indium, yttrium, niobium, tantalum, and vanadium, and the p-type semiconductor nanoparticles may comprise oxides of one or more metals selected from nickel and copper.

In the method for manufacturing a device comprising a charge transport layer of the present invention, the light absorption layer forming step may comprise applying a perovskite precursor solution on the first charge transport layer, and heating the transparent conductive substrate to which the solution is applied to a temperature between 65° C. and 150° C.

In the method for manufacturing a device comprising a charge transport layer of the present invention, the light absorption layer may comprise a perovskite light absorber that absorbs light to generate electrons and holes and the perovskite light absorber may have a chemical formula AMX₃ wherein A is a monovalent cation selected from the group consisting of CₙH₂ₙ₊₁NH₃⁺ (wherein n is an integer of 1 to 9), NH₄⁺, HC(NH₂)₂⁺, CS⁺ and a combination thereof, M is a divalent metal cation selected from the group consisting of Pb₂⁺, Sn₂⁺, Ge₂⁺, and a combination thereof, and X is a halogen anion.

In the method for manufacturing a device comprising a charge transport layer of the present invention, the perovskite precursor solution may contain one or more selected from N,N-dimethylmethanamide (DMF), dimethylsulfoxide (DMSO), N,N-dimethylacetamide (DMA), N-methyl-2-pyrrolidione (MPLD), N-methyl-2-pyridine (MPD), 2,6-dimethyl-γ-pyrone (DMP), acetamide, urea, thiourea (TU), N,N-dimethylthioacetamide (DMTA), thioacetamide (TAM), ethylenediamine (EN), tetramethylethylenediamine (TMEN), 2,2′-bipyridine (BIPY), 1,10-piperidine, aniline, pyrrolidine, diethylamine, N-methylpyrrolidine and n-propylamine as a solvent.

In the method for manufacturing a device comprising a charge transport layer of the present invention, the second charge transport layer may be a hole transport layer in which holes are majority carriers and may comprise single molecule hole transport materials or polymeric hole transport materials, wherein the single molecule hole transport materials may be Spiro-MeOTAD (2,2′,7,7′-tetrakis(N,N-p-dimethoxy-phenylamine)-9,9′-spirobifluorene) and the polymeric hole transport materials may be one or more selected from P3HT (poly(3-hexylthiophene)), PTAA (polytriarylamine), poly(3,4-ethylenedioxythiophene) and polystyrene sulfonate (PEDOT:PSS).

In the method for manufacturing a device comprising a charge transport layer of the present invention, the second charge transport layer may be a hole transport layer in which holes are majority carriers and may comprise at least one doping material selected from Li-based dopants and Co-based dopants.

In the method for manufacturing a device comprising a charge transport layer of the present invention, the second charge transport layer may comprise at least one selected from Li-TFSI (bis(trifluoromethane)sulfonimide lithium salt) and tBP (4-tert-butylpyridine).

A device comprising a charge transport layer manufactured by the method for manufacturing a device comprising a charge transport layer of the present invention may be a solar cell, a battery, or an LED.

### Effect of the Invention

The method for manufacturing a device comprising a charge transport layer of the present invention has the advantage of forming a uniform coating film with a thickness of about 20 nm or less even by only single coating with nanoparticles having a size of 5 to 10 nm. According to this method, an electron transport layer and a hole transport layer can be formed into a thin film having high crystallinity and no pin holes, and when manufacturing a perovskite solar cell on a large-area substrate according to the present invention can be implemented.

The method for manufacturing a device comprising a charge transport layer of the present invention is to form a charge transport layer on a transparent conductive substrate, and according to the method, it may be possible to stack a charge transport layer on a large-area substrate without defects such as pin holes.

### BRIEF DESCRIPTION OF DRAWINGS

FIG. 1 is a conceptual diagram showing a method for manufacturing a device comprising a charge transport layer of the present invention.

FIGS. 2a and 2b are scanning electron microscope (SEM) images of surfaces of the device manufactured by the method for manufacturing a device comprising a charge transport layer of the present invention and the device manufactured by a conventional solution process.

FIG. 3 is a graph comparing current density-voltage curves and photoelectric conversion efficiency results of the solar cell manufactured by the method for manufacturing a device comprising a charge transport layer of the present invention and the solar cell manufactured by a conventional solution process.

FIG. 4 is a graph comparing characteristics of the solar cell manufactured by the method for manufacturing a device comprising a charge transport layer of the present invention and the solar cell manufactured by a conventional solution process.

FIG. 5 is a graph comparing characteristics according to area size of the solar cell manufactured by the method for manufacturing a device comprising a charge transport layer of the present invention and the solar cell manufactured by a conventional solution process.

FIG. 6 is a graph comparing characteristics of modules of the solar cell manufactured by the method for manufacturing a device comprising a charge transport layer of the present invention and the solar cell manufactured by a conventional solution process.

### BEST MODE FOR CARRYING OUT THE INVENTION

Hereinafter, embodiments of the present invention will be described in detail with reference to the accompanying drawings. The size or shape of the components shown in the drawings may be exaggerated for clarity and convenience of description. In addition, terms specifically defined in consideration of the configuration and operation of the present invention may vary according to the intention or custom of users or operators. Definitions of these terms should be made based on the contents throughout this specification.

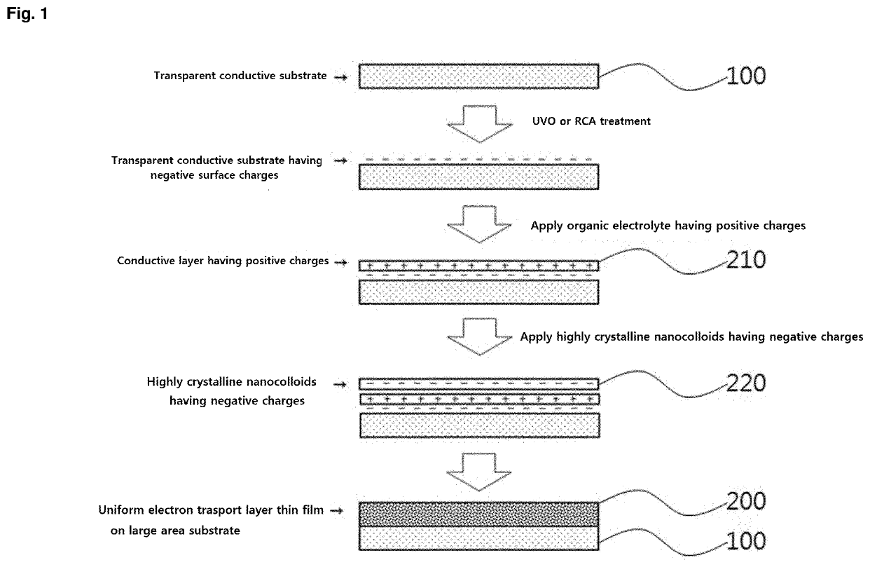

Hereinafter, a method for manufacturing a device comprising a charge transport layer according to the present invention will be described in detail with reference to FIGS. 1 to 5.

A perovskite solar cell may have a structure in which a transparent conductive substrate 100, a first charge transport layer 200, a light absorption layer (not shown), a second charge transport layer (not shown), and a rear electrode (not shown) are stacked. One of electrons and holes may be selected as majority carries of the first charge transport layer, and the other may be selected as majority carriers of the second charge transport layer.

The transparent conductive substrate 100 may be a transparent conductive oxide (TCO) substrate through which light passes. The transparent conductive substrate 100 may have a high transmittance in a visible light band and may be formed of a material having low electrical resistance.

The first charge transport layer 200 may be a layer that receives electrons or holes generated in the light absorption layer and transfers the electrons or holes to the transparent conductive substrate 100. The first charge transport layer 200 may be a layer in which electron transport materials or hole transport materials are stacked. The light absorption layer may be a layer that has a crystal structure of perovskite and absorbs light to generate electrons and holes. Electrons generated in the light absorption layer go to the electron transport layer, and holes generated in the light absorption layer go to the hole transport layer.

The second charge transport layer may be a layer that receives holes and electrons generated in the light absorption layer and transfers the holes and electrons to the rear electrode. For example, the second charge transport layer may be a layer in which hole transport materials are stacked if electron transport materials are stacked on the first charge transport layer 200. That is, the first charge transport layer 200 and the second charge transport layer may be stacked as the electron transport layer and the hole transport layer, respectively, on the front and rear surfaces of the light absorption layer.

The rear electrode is formed of silver or gold, and may receive holes or electrons from the second charge transport layer.

The method for manufacturing a device comprising a charge transport layer of the present invention is to form a charge transport layer on a transparent conductive substrate 100, and according to the method, it may be possible to stack a charge transport layer on a large-area substrate without defects such as pin holes.

As shown in FIG. 1, the method for manufacturing a device comprising a charge transport layer of the present invention may comprise a charge forming step of forming first polarity charges on a transparent conductive substrate 100, a polymer electrolyte coating forming step of forming a polymer electrolyte coating layer 210 of second polarity charges which have the opposite polarity to that of the first polarity charges on the transparent conductive substrate on which the first polarity charges are formed, and a first charge transport layer forming step of coating the polymer electrolyte coating layer 210 with nanoparticles having the first polarity charges so as to form a first charge transport layer 200.

First polarity charge may refer to a negative charge or a positive charge, and second polarity charge may refer to a charge having polarity opposite to the first polarity. That is, if the first polarity charge is a negative charge, the second polarity charge becomes a positive charge, and if the first polarity charge is a positive charge, the second polarity charge becomes a negative charge.

In one embodiment, in the negative charge forming step of forming negative charges on the transparent conductive substrate 100, the negative charges may be formed by treatment with at least one of UVO (ultraviolet-ozone), plasma, and RCA. In this embodiment, first polarity charges may be negative charges.

The UVO, plasma or RCA treatment may negatively charge the surface of the transparent conductive substrate 100. The surface of the substrate has a hydrophobic property (neutral or positive charge) having a carbon-carbon or carbon-hydrogen bond. Through the surface treatment, a carbonyl group, a carboxyl group, a hydroxyl group, a cyano group, etc. are formed so that the surface of the transparent conductive substrate 100 can be negatively charged at a uniform density.

The polymer electrolyte coating forming step may comprise preparing a polymer electrolyte solution by dissolving a conductive polymer in a basic solution, and applying the polymer electrolyte solution to the transparent conductive substrate 100.

The basic solution to be used in the polymer electrolyte coating forming step may be a solution obtained by titrating purified water to a pH of 8 to 15, preferably a pH of 9 to 12, and the pH may be at least 9, or at least 10 and 14 or less, 13 or less, 12 or less or 11 or less. The purified water is ultrapure water which may be prepared by completely removing dopants such as dissolved ions, solid particles, microorganisms, organic substances, and dissolved gases contained in water.

The conductive polymer may comprise one or more selected from PAH (polyallylamine hydrochloride), PDADMAC (poly(diallyldimethylammonium chloride)), PEI (poly(ethyleneimine)), PVBT (poly(vinylbenzyltriamethylamine)), PAN (polyaniline), PPY (polypyrrole) and poly(pyridium acetylene).

That is, the preparing a polymer electrolyte solution by dissolving a conductive polymer in a basic solution may be performed by dissolving a conductive polymer PAH in a solution obtained by titrating purified water to a pH of 10 to 15.

The polymer electrolyte solution may be coated on the transparent conductive substrate 100 by spin coating of the polymer electrolyte. Specifically, in the charge forming step, the polymer electrolyte having second polarity charges (for example, positive charges) may be coated on the surface of the transparent conductive substrate 100 on which first polarity charges (for example, negative charges) are uniformly formed, by spin coating. For example, the polymer electrolyte having positive charges may be uniformly coated without defects such as pin holes due to the negative charges uniformly distributed on the transparent conductive substrate 100. That is, forces such as centrifugal force applied during spin coating, attractive force between negative charges on the surface of the transparent conductive substrate 100 and positive charges of the polymer electrolyte, and repulsive force between the polymer electrolytes act comprehensively, so that the polymer electrolyte can be uniformly coated on the surface of the transparent conductive substrate 100 without defects such as pin holes.

The first charge transport layer forming step may comprise dispersing nanoparticles having first polarity charges in a polar solution and applying the solution in which the nanoparticles are dispersed on the polymer electrolyte coating layer.

When first polarity charges are negative charges, the pH value of the polar solution may be greater than or equal to the isoelectric point of the nanoparticles and when first polarity charges are positive charges, it may be equal to or less than the isoelectric point of the nanoparticles.

If first polarity charges are negative charges, the basic solution used in the first charge transport layer forming step may be an aqueous solution having a pH of 8 to 15. Preferably, it may be a solution obtained by titrating purified water to pH of 9 to 12.

The average size of the nanoparticles to be applied in the first charge transport layer forming step may be 5 to 10 nm.

The layer 220 in which nanoparticles having first polarity charges are stacked may have both of high electrical conductivity and visible light transmittance. When the thickness of nanoparticles to be stacked becomes larger than necessary, electron transfer characteristics and light transmittance may decrease. Accordingly, the thickness of nanoparticles to be stacked may be about 10 to 50 nm, preferably 10 to 30 nm, more preferably 15 to 25 nm or about 20 nm. The nanoparticles may have a size of 5 to 10 nm in consideration of the thickness of nanoparticles to be stacked. Through the charge forming step, the polymer electrolyte coating forming step and the first charge transport layer forming step of the present invention, nanoparticles and a target surface on which the nanoparticles are stacked may be more strongly charged with charges of opposite polarity to each other. Charges of strong polarity impart the reinforced attractive force, so that 2 to 3 nanoparticle layers can be formed on the polymer electrolyte coating layer by only single process. That is, by only single coating with nanoparticles having a size of 5 to 10 nm, the nanoparticles may be stacked with a thickness of about 20 nm.

Nanoparticles used in the method for manufacturing a device comprising a charge transport layer may be n-type semiconductor nanoparticles or p-type semiconductor nanoparticles. Specifically, the n-type semiconductor nanoparticles may comprise oxides of one or more metals selected from aluminum, titanium, tin, zinc, tungsten, zirconium, gallium, indium, yttrium, niobium, tantalum, and vanadium, and the p-type semiconductor nanoparticles may comprise oxides of one or more metals selected from nickel and copper and may have a negative charge by the surface treatment. Nanoparticles may have a negative charge or positive charge due to the zeta potential by adjusting the pH of the polar solution.

The solution in which nanoparticles having first polarity charges are dispersed may be coated on the polymer electrolyte coating layer 210. For example, nanoparticles having first polarity charges may be uniformly stacked on the polymer electrolyte coating layer 210 by spin coating. Alternatively, the first charge transport layer 200 may be formed on the polymer electrolyte coating layer 210 by dip coating in which the transparent conductive substrate 100 is dipped in the solution in which nanoparticles having first polarity charges are dispersed.

Nanoparticles having first polarity charges may also be uniformly stacked by interacting with second polarity charges formed on the polymer electrolyte coating layer 210.

After the polymer electrolyte coating layer 210 and the nanoparticle layer 220 having first polarity charges are stacked on the transparent conductive substrate 100, a heat treatment process of heating the transparent conductive substrate 100 is performed and the first charge transport layer 200 may be formed on the transparent conductive substrate 100.

The polymer electrolyte coating layer 210 and the layer 220 having nanoparticles stacked may correspond to the first charge transport layer 200. That is, the first charge transport layer 200 may be a layer containing a polymer electrolyte and nanoparticles. The polymer electrolyte and nanoparticles can form highly crystalline nanocolloids, and can form a uniform charge transport layer on a large-area substrate through self-assembly using electrical interconnection between charges on the substrate.

In the method for manufacturing a device comprising a charge transport layer of the present invention, the charge transport layer forming step yield a charge transport layer having a desired thickness even through only one performing.

The method for manufacturing a device comprising a charge transport layer of the present invention may comprise, after the first charge transport layer forming step, a light absorption layer forming step of forming a light absorption layer on the first charge transport layer 200, a second charge transport layer forming step of forming a second charge transport layer on the light absorption layer, and an electrode forming step of forming an electrode on the second charge transport layer.

The light absorption layer forming step may comprise applying a perovskite precursor solution on the first charge transport layer 200, and heating the transparent conductive substrate 100 to which the solution is applied to a temperature between 65° C. and 150° C.

In the method for manufacturing a device comprising a charge transport layer of the present invention, the light absorption layer may comprise a perovskite light absorber that absorbs light to generate electrons and holes and the perovskite light absorber may have a chemical formula AMX₃.

A may include a monovalent cation selected from the group consisting of CₙH₂ₙ₊₁NH₃⁺ (wherein n is an integer of 1 to 9), NH₄⁺, HC(NH₂)₂⁺, CS⁺ and a combination thereof.

M may include a divalent metal cation selected from the group consisting of Pb₂⁺, Sn₂⁺, Ge₂⁺, and a combination thereof.

X is a halogen anion.

The perovskite precursor solution may contain one or more selected from N,N-dimethylmethanamide (DMF), dimethylsulfoxide (DMSO), N,N-dimethylacetamide (DMA), N-methyl-2-pyrrolidione (MPLD), N-methyl-2-pyridine (MPD), 2,6-dimethyl-γ-pyrone (DMP), acetamide, urea, thiourea (TU), N,N-dimethylthioacetamide (DMTA), thioacetamide (TAM), ethylenediamine (EN), tetramethylethylenediamine (TMEN), 2,2′-bipyridine (BIPY), 1,10-piperidine, aniline, pyrrolidine, diethylamine, N-methylpyrrolidine and n-propylamine as a solvent.

Specifically, the perovskite precursor solution may be a solution in which CH₃NH₃I, PbI₂ and (CH₃)₂SO in a ratio of about 1:1:1 are dissolved in N,N-dimethylmethanamide at about 20 wt % or more, 30 wt % or more, or 40 wt or more and 80 wt % or less, 70 wt % or less, or 60 wt % or less, and in one embodiment, at about 50 wt %. The perovskite precursor solution applied on the first charge transport layer 200 may be stacked by spin coating and coated as a light absorption layer.

For example, in the light absorption layer forming step, a perovskite precursor solution in which CH₃NH₃I, PbI₂ and (CH₃)₂SO in a ratio of about 1:1:1 are dissolved at about 50 wt % in N,N-dimethylmethanamide, may be coated on the first charge transport layer 200 by spin coating, for example, and the coated perovskite precursor may be heated to 65° C. to 150° C. to form a light absorption layer.

The second charge transport layer may comprise single-molecule hole transport materials or polymeric hole transport materials when the first charge transport layer is an electron transport layer in which electrons are majority carriers, but is not limited thereto. For example, when the second charge transport layer is a hole transport layer, Spiro-MeOTAD (2,2′,7,7′-tetrakis(N,N-p-dimethoxy-phenylamino)-9,9′-spirobifluorene) may be used as the single molecule hole transport material, and P3HT (poly(3-hexylthiophene)), PTAA (polytriarylamine), poly(3,4-ethylenedioxythiophene), or polystyrene sulfonate (PEDOT:PSS) may be used as the polymeric hole transport material, but is not limited thereto. In addition, for example, the hole transport layer (HTM) may be doping materials selected from the group consisting of Li-based dopants, Co-based dopants, and a combination thereof, but is not limited thereto.

Specifically, a mixture of Spiro-MeOTAD, Li-TFSI (bis(trifluoromethane)sulfonimide lithium salt) and tBP (4-tert-butylpyridine) may be used, but is not limited thereto.

The second charge transport layer may be formed by spin coating a hole transfer solution on the light absorption layer.

When the first charge transport layer is a hole transport layer in which holes are majority carriers, the second charge transport layer may be formed as an electron transport layer in which electrons are majority carriers.

When the second charge transport layer is an electron transport layer, the second charge transport layer may comprise oxides of one or more metals selected from n-type semiconductor aluminum, titanium, tin, zinc, tungsten, zirconium, gallium, indium, yttrium, niobium, tantalum, and vanadium as electron transport materials.

An electrode including, but not limited to, at least one of aluminum Al), calcium (Ca), silver (Ag), zinc (Zn), gold (Au), platinum (Pt), copper (Cu), and chromium (Cr) may be formed on the second charge transport layer.

A device comprising a charge transport layer of the present invention may be manufactured by the method for manufacturing a device comprising a charge transport layer comprising a charge forming step, a polymer electrolyte coating forming step, a first charge transport layer forming step, a light absorption layer forming step, a second charge transport layer forming step and an electrode forming step.

The device comprising a charge transport layer may be used in the fields of light absorbing or emitting devices, storage devices such as batteries or LED devices, in addition to perovskite solar cells.

### MODE FOR CARRYING OUT THE INVENTION

Hereinafter, a specific embodiment of manufacturing a perovskite solar cell according to the method for manufacturing a device comprising a charge transport layer of the present invention will be described in detail.

An embodiment in which the first charge transport layer is an electron transport layer, the second charge transport layer is a hole transport layer, and the first polarity charges and second polarity charges are negative charges and positive charges, respectively, will be described in detail.

1) Surface Treatment of Transparent Conductive Substrate

A UVO treatment with ultraviolet rays of 184.9 nm and 253.7 nm wavelength was performed for 10 minutes by using a UVO device on an FTO substrate as a transparent conductive substrate to form a transparent conductive substrate in which negative charges were uniformly distributed.

2) Formation of Polymer Electrolyte Layer

1 mg of PAH was added to 1 mL of a basic solution obtained by titrating purified water to a pH of 11 with adding NaOH, followed by stirring to prepare a polymer electrolyte solution. The prepared polymer electrolyte solution was spin-coated on the surface of the transparent conductive substrate in which negative charges were distributed, thereby forming a positive surface charges such that the zeta potential of the substrate surface was about +30 mV or more.

3) Formation of Electron Transport Layer

2 wt % of SnO₂ particles having an average particle size of about 7 nm were dispersed in a basic solution titrated to pH 11. The solution in which SnO₂ particles having a surface zeta potential of about −20 mV or less were dispersed was spin-coated on the polymer electrolyte coating layer to form an electron transport layer.

4) Formation of Perovskite Light Absorption Layer

A solution in which CH₃NH₃I, PbI₂ and (CH₃)₂SO in a molar ratio of 1:1:1 were dissolved at 50 wt % in dimethylformamide (N,N-dimethylmethanamide, DMF), was spin-coated on the electron transport layer and heated to a temperature of 65° C. to 150° C. to form a light absorption layer.

5) Formation of Hole Transport Layer

36 mg of Spiro-MeOTAD was dissolved in 0.5 mL of chlorobenzene, and 14.4 μL of tBP and about 8.8 μL of a solution containing 520 mg of Li-TFSI dissolved in 1 mL of acetonitrile were added thereto. The resulting solution was spin-coated on the light absorption layer to form a hole transport layer.

6) Formation of Electrode

Gold was deposited to a thickness of 80 nm on the hole transport layer by using a thermal evaporator to form an electrode.

### Comparative Example

1) Surface Treatment of Transparent Conductive Substrate

A UVO treatment with ultraviolet rays of 184.9 nm and 253.7 nm wavelength was performed for 10 minutes by using a UVO device on an FTO substrate as a transparent conductive substrate to form a transparent conductive substrate in which negative charges were uniformly distributed.

2) Formation of Electron Transport Layer

2 wt % of SnO₂ particles having an average particle size of about 7 nm were dispersed in purified water. The solution in which SnO₂ particles were dispersed was spin-coated on the transparent conductive substrate to form an electron transport layer.

3) Formation of Perovskite Light Absorption Layer

A solution in which CH₃NH₃I, PbI₂ and (CH₃)₂SO in a molar ratio of 1:1:1 were dissolved at 50 wt % in dimethylformamide (N,N-dimethylmethanamide), was spin-coated on the electron transport layer and heated to a temperature of 65° C. to 150° C. to form a light absorption layer.

4) Formation of Hole Transport Layer

36 mg of Spiro-MeOTAD was dissolved in 0.5 mg of chlorobenzene, and 14.4 μL of tBP and about 8.8 μL of a solution containing 520 mg of Li-TFSI dissolved in 1 mL of acetonitrile were added thereto. The resulting solution was spin-coated on the light absorption layer to form a hole transport layer.

5) Formation of Electrode

Gold was deposited to a thickness of 80 nm on the hole transport layer using a thermal evaporator to form an electrode.

### Experimental Example

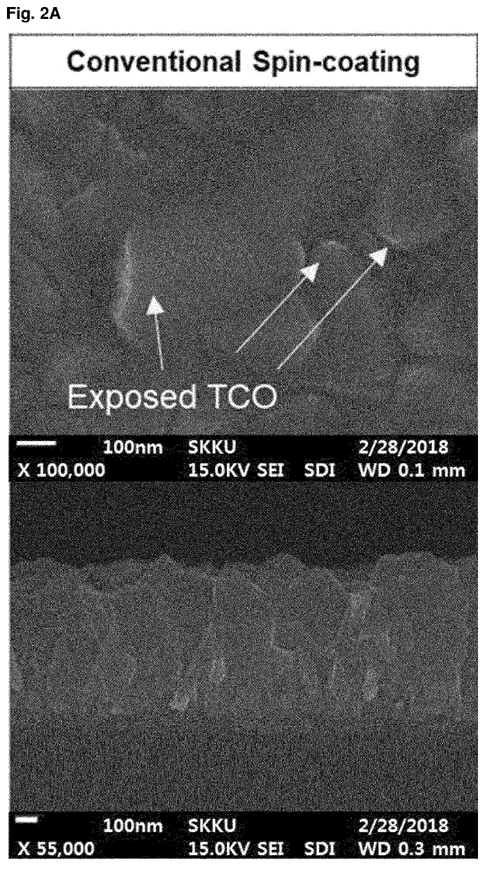

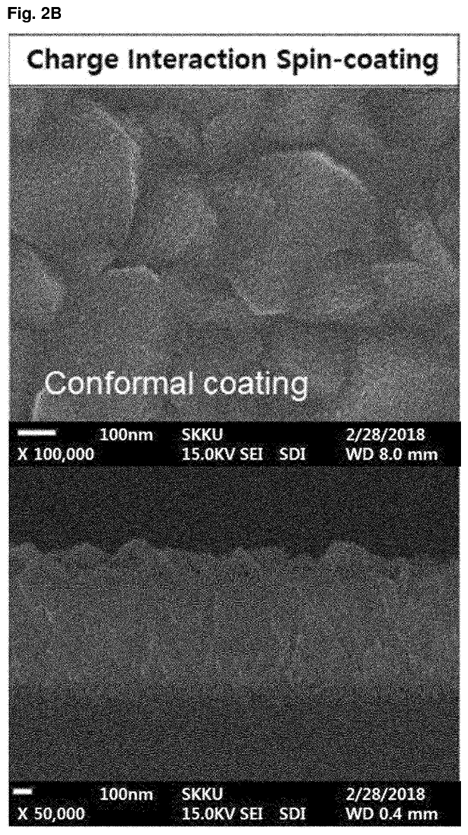

FIGS. 2a and 2b are results of scanning electron microscope (SEM) photographing surfaces of devices manufactured by the methods of Comparative Examples and Examples. FIG. 2a shows a surface of a device manufactured by the conventional spin coating method (Comparative Example) and FIG. 2b shows a surface of a device manufactured by the method for manufacturing a device comprising a charge transport layer of the present invention (Example). As shown in FIGS. 2a and 2b, it is observed that the surface of the device manufactured by the conventional solution process is not coated, and the surface of the TCO substrate, a transparent conductive substrate 100, is exposed as it is. On the other hand, a uniform coating layer is formed on the surface of the transparent conductive substrate 100 of the device manufactured by the method for manufacturing a device comprising a charge transport layer of the present invention.

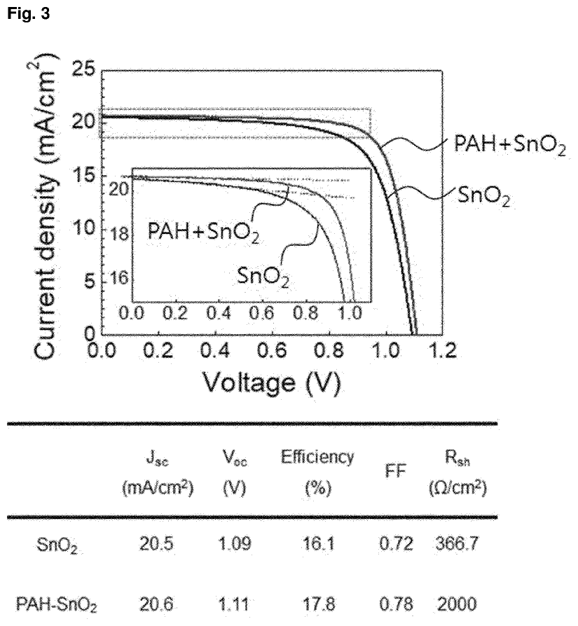

FIG. 3 is a graph comparing current density-voltage curves and photoelectric conversion efficiency results of solar cells manufactured by the method of Example (PAH+SnO₂) and Comparative Example (SnO₂) As shown in FIG. 3, the current density-voltage curve of Example (PAH+SnO₂) has more square shape than the current density-voltage curve of Comparative Example (SnO₂) A solar cell manufactured according to the method of manufacturing a device comprising a charge transport layer of the present invention exhibits better efficiency.

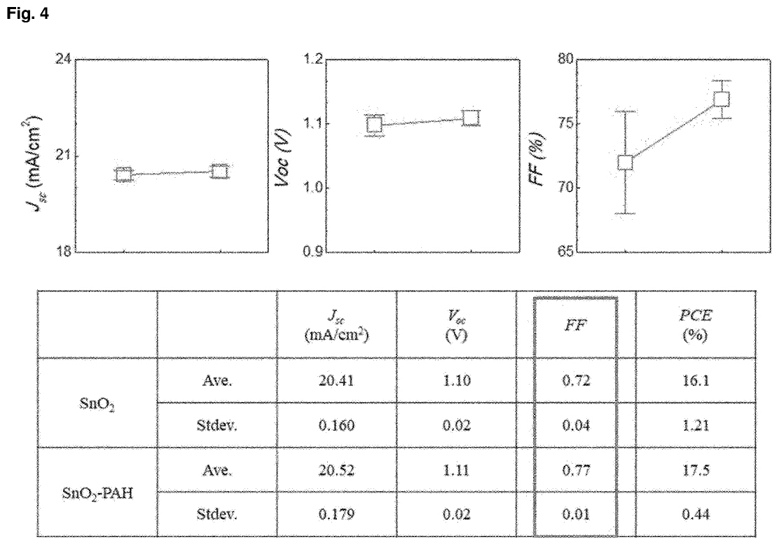

FIG. 4 is a graph comparing characteristics of solar cells manufactured by the method of Example (PAH+SnO₂) and Comparative Example (SnO₂)

J_{SC} (short-circuit current) is the current density in the reverse direction when the solar cell is short-circuited, that is, receives light in the absence of external resistance. This value indicates how effectively electrons and holes are sent from the inside of the battery to the external circuit without loss due to recombination between electrons and holes excited by light absorption.

V_{OC} (open-circuit voltage) is the difference of electrical potential between two terminals of a solar cell when receiving light while the circuit is open, that is, an infinite impedance is applied. This value can be determined by the band gap of the semiconductor.

FF (fill factor) is a value obtained by dividing the product of the current density and voltage at the maximum power point by the product of J_{SC} and V_{OC}. That is, it is an index indicating the degree to which the current density-voltage curve approximates a square shape.

PCE (power conversion efficiency) is the ratio of converting light energy into electrical energy.

As shown in FIG. 4, the solar cell manufactured by the method for manufacturing a device comprising a charge transport layer of the present invention exhibits a high average value for all values of J_{SC}, V_{OC}, FF and PCE and a lower standard deviation value for FF and PCE.

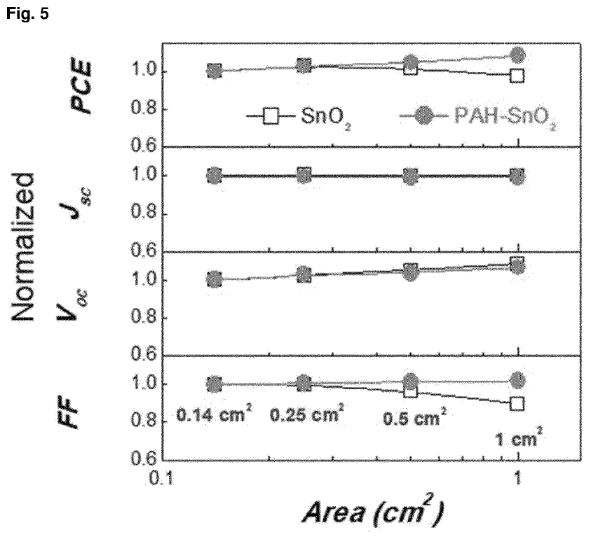

FIG. 5 is a graph comparing characteristics according to area size of solar cells manufactured by the method of Example (PAH+SnO₂) and Comparative Example (SnO₂) Specifically, it shows the J_{SC}, V_{OC}, FF, and PCE characteristic values of the solar cell with area size of 0.14 cm², 0.25 cm², 0.5 cm², and 1 cm². As shown in FIG. 5, as the area size increases, the values of FF and PCE are better in case of the solar cell manufactured by the method for manufacturing a device comprising a charge transport layer of the present invention.

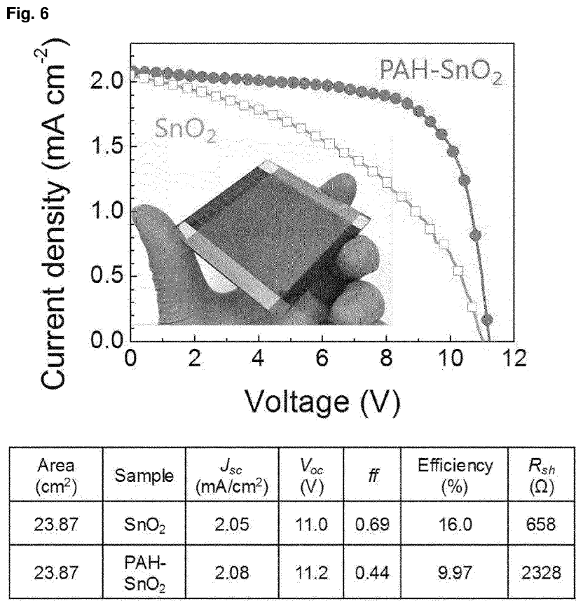

FIG. 6 is a graph comparing efficiency according to area size of modules of solar cells manufactured by the method of Example (PAH+SnO₂) and Comparative Example (SnO₂) It shows the J_{SC}, V_{OC}, FF, and PCE characteristic values of the solar cell module with area size of 5×5 cm². In particular, in the case of Comparative Example, FF and efficiency were rapidly decreased due to the rapid decrease in the shunt resistance, but in the case of Example, excellent module efficiency characteristics of 16.0% were shown without decrease in the shunt resistance.

Although the embodiments according to the present invention have been described above, these are merely exemplary, and those of ordinary skill in the art will understand that various modifications and equivalents of embodiments are possible therefrom. Therefore, the true technical protection scope of the present invention should be determined by the following claims.

### INDUSTRIAL AVAILABILITY

The method for manufacturing a device comprising a charge transport layer of the present invention has the advantage of forming a uniform coating film with a thickness of about 20 nm or less even by only single coating with nanoparticles having a size of 5 to 10 nm. According to this method, an electron transport layer and a hole transport layer can be formed into a thin film having high crystallinity and no pin holes, and when manufacturing a perovskite solar cell on a large-area substrate according to the present invention can be implemented.

The method for manufacturing a device comprising a charge transport layer of the present invention is to form a charge transport layer on a transparent conductive substrate, and according to the method, it may be possible to stack a charge transport layer on a large-area substrate without defects such as pin holes.

1. A method for manufacturing a device comprising a charge transport layer, comprising:
a charge forming step of forming first polarity charges on a transparent conductive substrate,
a polymer electrolyte coating forming step of forming a polymer electrolyte coating layer of second polarity charges which have the opposite polarity to that of the first polarity charges on the transparent conductive substrate on which the first polarity charges are formed, and
a first charge transport layer forming step of coating the polymer electrolyte coating layer with nanoparticles having the first polarity charges so as to form a first charge transport layer.

2. The method for manufacturing a device comprising a charge transport layer according to claim 1, comprising:
after the first charge transport layer forming step,
a light absorption layer forming step of forming a light absorption layer on the first charge transport layer,
a second charge transport layer forming step of forming a second charge transport layer on the light absorption layer, and
an electrode forming step of forming an electrode on the second charge transport layer.

3. The method for manufacturing a device comprising a charge transport layer according to claim 2, wherein one of electrons and holes is selected as majority carries of the first charge transport layer, and the other is selected as majority carriers of the second charge transport layer.

4. The method for manufacturing a device comprising a charge transport layer according to claim 1, wherein in the charge forming step, first polarity charges are formed on the transparent conductive substrate by treatment with at least one of UVO (ultraviolet-ozone), plasma, and RCA.

5. The method for manufacturing a device comprising a charge transport layer according to claim 1, wherein the polymer electrolyte coating forming step comprises:
preparing a polymer electrolyte solution by dissolving a conductive polymer in a basic solution, and
applying the polymer electrolyte solution to the transparent conductive substrate.

6. The method for manufacturing a device comprising a charge transport layer according to claim 5, wherein the conductive polymer comprises one or more selected from PAH (polyallylamine hydrochloride), PDADMAC (poly (diallyldimethylammonium chloride)), PEI (poly(ethyleneimine)), PVBT (poly(vinylbenzyltriamethylamine)), PAN (polyaniline), PPY (polypyrrole) and poly(pyridium acetylene).

7. The method for manufacturing a device comprising a charge transport layer according to claim 1, wherein the first charge transport layer forming step comprises:
dispersing the nanoparticles having the first polarity charges in a polar solution, and
applying the solution in which the nanoparticles are dispersed on the polymer electrolyte coating layer.

8. The method for manufacturing a device comprising a charge transport layer according to claim 7, wherein when first polarity charges are negative charges, a pH value of the polar solution is greater than or equal to the isoelectric point of the nanoparticles, and when first polarity charges are positive charges, a pH value of the polar solution is equal to or less than the isoelectric point of the nanoparticles.

9. The method for manufacturing a device comprising a charge transport layer according to claim 7, wherein the first polarity charges are negative charges, and the polar solution is a basic solution which is an aqueous solution having a pH of 8 to 15.

10. The method for manufacturing a device comprising a charge transport layer according to claim 7, wherein the first charge transport layer forming step is performed one time.

11. The method for manufacturing a device comprising a charge transport layer according to claim 7, wherein an average size of the nanoparticles is 5 to 10 nm.

12. The method for manufacturing a device comprising a charge transport layer according to claim 7, wherein the nanoparticles are n-type semiconductor nanoparticles or p-type semiconductor nanoparticles.

13. The method for manufacturing a device comprising a charge transport layer according to claim 12, wherein the n-type semiconductor nanoparticles comprise oxides of one or more metals selected from aluminum, titanium, tin, zinc, tungsten, zirconium, gallium, indium, yttrium, niobium, tantalum, and vanadium, and the p-type semiconductor nanoparticles comprise oxides of one or more metals selected from nickel and copper.

14. The method for manufacturing a device comprising a charge transport layer according to claim 2, wherein the light absorption layer forming step comprises:
applying a perovskite precursor solution on the first charge transport layer, and
heating the transparent conductive substrate to which the solution is applied to a temperature between 65° C. and 150° C.

15. The method for manufacturing a device comprising a charge transport layer according to claim 14, wherein the light absorption layer comprises a perovskite light absorber that absorbs light to generate electrons and holes and
the perovskite light absorber has a chemical formula AMX₃ wherein A is a monovalent cation selected from the group consisting of CₙH₂ₙ₊₁NH₃⁺ (wherein n is an integer of 1 to 9), NH₄⁺, HC(NH₂)₂⁺, CS⁺ and a combination thereof, M is a divalent metal cation selected from the group consisting of Pb₂⁺, Sn₂⁺, Ge₂⁺, and a combination thereof, and X is a halogen anion.

16. The method for manufacturing a device comprising a charge transport layer according to claim 14, wherein the perovskite precursor solution contains one or more selected from N,N-dimethylmethanamide (DMF), dimethylsulfoxide (DMSO), N,N-dimethylacetamide (DMA), N-methyl-2-pyrrolidione (MPLD), N-methyl-2-pyridine (MPD), 2,6-dimethyl-γ-pyrone (DMP), acetamide, urea, thiourea (TU), N,N-dimethylthioacetamide (DMTA), thioacetamide (TAM), ethylenediamine (EN), tetramethylethylenediamine (TMEN), 2,2′-bipyridine (BIPY), 1,10-piperidine, aniline, pyrrolidine, diethylamine, N-methylpyrrolidine and n-propylamine as a solvent.

17. The method for manufacturing a device comprising a charge transport layer according to claim 3, wherein when the second charge transport layer is the hole transport layer in which holes are majority carries, the second charge transport layer comprises single molecule hole transport materials or polymeric hole transport materials, and
when the second charge transport layer is the electron transport layer in which electrons are majority carries, the second charge transport layer comprises electron transport materials, and
wherein the single molecule hole transport materials are Spiro-MeOTAD (2,2′,7,7′-tetrakis(N,N-p-dimethoxy-phenylamino)-9,9′-spirobifluorene),
the polymeric hole transport materials are one or more selected from P3HT (poly(3-hexylthiophene)), PTAA (polytriarylamine), poly(3,4-ethylenedioxythiophene) and polystyrene sulfonate (PEDOT:PSS), and
the electron transport materials comprise oxides of one or more metals selected from n-type semiconductor aluminum, titanium, tin, zinc, tungsten, zirconium, gallium, indium, yttrium, niobium, tantalum, and vanadium.

18. The method for manufacturing a device comprising a charge transport layer according to claim 2, wherein the second charge transport layer is a hole transport layer in which holes are majority carriers and comprises at least one doping material selected from Li-based dopants and Co-based dopants.

19. The method for manufacturing a device comprising a charge transport layer according to claim 18, wherein the second charge transport layer comprises at least one selected from Li-TFSI (bis(trifluoromethane)sulfonimide lithium salt) and tBP (4-tert-butylpyridine).

20. A device comprising a charge transport layer manufactured by the method of claim 1.

21. (canceled)
